(19) United States
(12) Patent Application Publication
(10) Pub. No.: US 2025/0141965 A1
(43) Pub. Date: May 1, 2025

(54) Method and Device for Testing Vehicle Data Consistency in Vehicle to Everything (V2X)

(71) Applicant: CATARC Automotive Test Center (Tianjin) Co., Ltd., Tianjin (CN)

(72) Inventors: Feiyan WU, Tianjin (CN); Guokai JIANG, Tianjin (CN); Xuebin SHAO, Tianjin (CN); Hang SUN, Tianjin (CN); Xiaodi TIAN, Tianjin (CN); Bowei ZOU, Tianjin (CN); Anlu YUAN, Tianjin (CN); Fujian HE, Tianjin (CN); Chun LI, Tianjin (CN); Rupeng DOU, Tianjin (CN); Jiaxu FENG, Tianjin (CN); Dandan WU, Tianjin (CN); Yu WANG, Tianjin (CN); Zhiqiang Yang, Tianjin (CN); Shasha TANG, Tianjin (CN); Jiaoyang LIU, Tianjin (CN); Mengdan WANG, Tianjin (CN); Xiucheng LI, Tianjin (CN); Xiaolong ZHAO, Tianjin (CN); Jinna FAN, Tianjin (CN); Quan WEN, Tianjin (CN); Fenghe LIU, Tianjin (CN); Dongdong WU, Tianjin (CN)

(21) Appl. No.: 18/924,790

(22) Filed: Oct. 23, 2024

(30) Foreign Application Priority Data
Oct. 25, 2023 (CN) 202311384522.1

(51) Int. Cl. H04L 67/12; G01R 29/08; G07C 5/04; H04W 24/06; H04W 92/18

(52) U.S. Cl. CPC H04L 67/12; G01R 29/0821; G07C 5/04; H04W 24/06; H04W 92/18

(57) ABSTRACT

The present application relates to the field of data consistency testing, and provides a method and device for testing vehicle data consistency in V2X. The method includes: collecting vehicle V2X test data transmitted based on a V2X-PC5 communication protocol; parsing the V2X test data, and determining whether a format and a data value of parsed data conform to a preset definition, and whether the parsed data is consistent with operating data in testing, to obtain a data structure consistency result; calculating an average error value between dynamic data in the parsed data and data collected by a high-precision inertial navigation device when time stamps are aligned and data sampling frequencies are the same; and according to the data structure consistency result and the average error value, determining whether vehicle data conforms to a preset consistency standard.

### CROSS REFERENCE TO RELATED APPLICATION

This patent application claims the benefit and priority of Chinese Patent Application No. 202311384522.1, filed with the China National Intellectual Property Administration on Oct. 25, 2023, the disclosure of which is incorporated by reference herein in its entirety as part of the present application.

### TECHNICAL FIELD

The present application relates to the field of data consistency testing, and in particular, to a method and device for testing vehicle data consistency in vehicle to everything (V2X).

### BACKGROUND

V2X-PC5 is a V2X communication technology that facilitates wireless communication between vehicles and between vehicles and infrastructure through vehicle-to-infrastructure and vehicle-to-vehicle communication. PC5 refers to vehicle communication utilizing the 5.9 GHZ band. V2X-PC5 technology enables real-time, two-way communication between vehicles and infrastructure, to exchange data such as vehicle status, traffic information, and safety alerts. By using V2X-PC5 communication, vehicles can detect presence of each other and share critical information, contributing to a safer and more efficient road environment.

The V2X-PC5 technology has a broad range of applications, including autonomous driving, intelligent transportation systems, traffic management, and road safety. It facilitates real-time data exchange and collaborative operation between vehicles and infrastructure, helping improve traffic efficiency, reduce accidents, and provide drivers with more comprehensive road information and warnings.

During data processing, the V2X-PC5 data collection, recording, and parsing system is crucial for collecting, parsing, and processing data used in V2X-PC5 communication. The system parses the received V2X-PC5 data packets and provides functions to verify the data accuracy and completeness, ensuring that the quality of data sent by vehicles meets the requirements for early warning applications.

However, there is currently no technical solution for testing vehicle data consistency in V2X based on the V2X-PC5 communication technology.

### SUMMARY

In view of the defects or deficiencies in the prior art, the purpose of the present application is to provide a method and device for testing vehicle data consistency in V2X, to realize vehicle data consistency testing in V2X based on the V2X-PC5 communication technology.

The present application provides a method for testing vehicle data consistency in V2X, including:
collecting vehicle V2X test data transmitted based on a V2X-PC5 communication protocol;
parsing the V2X test data, and determining whether a format and a data value of parsed data conform to a preset definition, and whether the parsed data is consistent with operation data in vehicle testing, to obtain a data structure consistency result;
calculating an average error value between dynamic vehicle driving data in the parsed data and vehicle driving data collected by an inertial navigation device when time stamps are aligned and data sampling frequencies are the same; and
according to the data structure consistency result and the average error value, determining whether vehicle data conforms to a preset consistency standard.

Optionally, said determining whether a format and a data value of parsed data conform to a preset definition includes:
determining whether the parsed data conforms to a format of a basic safety message (BSM).

Optionally, said determining whether a data value conforms to a preset definition includes:
determining whether the data value falls between a data value range defined during testing.

Optionally, the V2X test data includes shielded chamber static test data, shielded chamber dynamic test data, and shielded chamber event trigger test data.

Optionally, steps for obtaining the shielded chamber static test data include:
driving a vehicle under test into a shielded chamber, fixing the vehicle on a turntable, and powering off the vehicle;
starting a V2X PC5 message receiving instrument, to start recording basic safety messages (BSMs) from the vehicle;
starting the vehicle under test and simultaneously starting a global navigation satellite system (GNSS) simulator to send vehicle static information;
restarting the vehicle under test to restart sending BSMs, and recoding, by the V2X PC5 message receiving instrument, all BSMs received; and
repeating the previous step to obtain a plurality of pieces of vehicle test data corresponding to the vehicle static information.

Optionally, steps for obtaining the shielded chamber dynamic test data include:
driving a vehicle under test into a shielded chamber, fixing the vehicle on a turntable, and powering off the vehicle;
starting a V2X PC5 message receiving instrument, to start recording basic safety messages (BSMs) from the vehicle;
starting the vehicle under test and simultaneously starting a global navigation satellite system (GNSS) simulator to send vehicle dynamic data;
controlling an error between a rolling linear speed of the turntable and a speed in a GNSS trajectory to be within ±1 km/h, and a heading angle of the vehicle under test to be consistent with direction data in the GNSS trajectory;
guiding by voice, a driver of the vehicle under test to perform a driving action, and starting sending BSMs; and
recording, by the V2X PC5 message receiving instrument, all BSMs received, to obtain vehicle test data corresponding to the vehicle dynamic information.

Optionally, steps for obtaining the shielded chamber event trigger test data include:
driving a vehicle under test into a shielded chamber, fixing the vehicle on a turntable, and powering off the vehicle;
starting a V2X PC5 message receiving instrument, to start recording basic safety messages (BSMs) from the vehicle;
starting the vehicle under test and simultaneously starting a global navigation satellite system (GNSS) simulator to send vehicle dynamic data;
controlling an error between a rolling linear speed of the turntable and a speed in a GNSS trajectory to be within ±1 km/h, and a heading angle of the vehicle under test to be consistent with direction data in the GNSS trajectory;
guiding by voice, a driver of the vehicle under test to trigger a defined event, and starting sending BSMs; and
recording, by the V2X PC5 message receiving instrument, all BSMs received, to obtain vehicle test data corresponding to the vehicle dynamic information.

Optionally, experimental conditions for obtaining the test data include:
a laboratory test environment is an anechoic chamber; and
a road test environment meets open sky environment requirements.

Optionally, the BSM includes the following types:
mandatory: indicating that a system sends a data unit in each cycle;
conditionally mandatory: indicating that a system sends a data unit when a specific triggering condition is met;
optional: indicating that a system autonomously determines whether or not to send a data unit; and
not required: indicating that a system does not send a data unit.

The present application further provides a device for testing vehicle data consistency in V2X, includes: a V2X-PC5 module and a processing module, where
the V2X-PC5 module receives basic safety messages (BSMs) sent by a vehicle under test; and
the processing module is configured to: collect vehicle V2X test data; parse the V2X test data, and determine whether a format and a data value of parsed data conform to a preset definition, and whether the parsed data is consistent with operation data in vehicle testing, to obtain a data structure consistency result; calculate an average error value between dynamic data in the parsed data and data collected by a high-precision inertial navigation device when time stamps are aligned and data sampling frequencies are the same; and according to the data structure consistency result and the average error value, determine whether vehicle data conforms to a preset consistency standard.

The advantages and beneficial effects of the present application are as follows:

The present application provides a method for testing vehicle data consistency in V2X. The method includes: collecting vehicle V2X test data transmitted based on a V2X-PC5 communication protocol; parsing the V2X test data, and determining whether a format and a data value of parsed data conform to a preset definition, and whether the parsed data is consistent with operation data in vehicle testing, to obtain a data structure consistency result; calculating an average error value between dynamic data in the parsed data and data collected by a high-precision inertial navigation device when time stamps are aligned and data sampling frequencies are the same; and according to the data structure consistency result and the average error value, determining whether vehicle data conforms to a preset consistency standard. By comparing the consistency of data formats, numerical values, and numerical errors of data collected via V2X-PC5, the present application achieves consistency testing for vehicle data in V2X-PC5 communication, addressing the current gap in relevant testing methods.

### BRIEF DESCRIPTION OF THE DRAWINGS

FIG. 1 is a schematic diagram of testing vehicle data consistency in V2X according to the present application;

FIG. 2 is a schematic diagram of testing vehicle data consistency in a first shielded chamber environment according to the present application;

FIG. 3 is a schematic diagram of testing vehicle data consistency in a second shielded chamber environment according to the present application;

FIG. 4 is a schematic diagram of testing vehicle data consistency in an open field according to the present application; and

FIG. 5 is a schematic installation diagram of testing vehicle data consistency in V2X according to the present application.

### DETAILED DESCRIPTION OF THE EMBODIMENTS

The present application will be further described in combination with accompanying drawings and specific examples so as to enable those skilled in the art to better understand and practice the present application.

A method for testing vehicle data consistency in V2X according to the present application belongs to the technical field of data consistency testing and addresses the current lack of relevant testing methods.

According to the method for testing vehicle data consistency in V2X, vehicle V2X test data is received based on a V2X PC5 communication technology for consistency testing, so as to implement vehicle data consistency testing in V2X.

In the present application, a test device in a V2X-PC5 data collection, recording, and parsing system collects, records, and parses V2X-PC5 data and performs analysis and evaluation. The test device has the following features and functions:

Device specifications: The device features a high-performance processor and memory, supporting large-capacity data storage. The device includes a high-speed network interface for rapid data transmission and supports L1/L2 dual-frequency multimode reception, real-time kinematic (RTK), and inertial navigation, providing centimeter-level positioning precision at 10 Hz. Further, the device accommodates various differential data sources and cooperation methods, offers high-precision map access for lane-level business scenarios, and includes a visual interface with related software for convenient data analysis and evaluation by the user.

Advanced core services: The device provides advanced core services for V2X business logic and test data analysis tools. Conditional optional functions are supported in each functional module.

A communication plane (Comm Plane) provides various V2X logic communication mechanisms, meeting user demands for rapid development and integration, and supports user-defined business logic development. Comm Plane offers flexible and configurable communication functions, supports private message channels, enables network-transparent transmission channels for upper computers, includes congestion control algorithms, and facilitates the forwarding of air interface messages.

A data plane (Data Plane) manages vehicle and V2X data, ensures uniformity of data interfaces, and provides data preprocessing capabilities. Data Plane provides capabilities such as data management, data visualization management, PP/PH support, data preprocessing, and data validity management.

A collaborative driver assistance system plane (CDAS Plane) implements a variety of security and traffic applications.

A management plane (Mng Plane) provides basic configuration functions for the protocol stack.

The process of operating the device is as follows:

Connect the test device to a V2X device under test and perform corresponding settings. Start the test device and start collecting data.

Once data collection is completed, transfer the data to relevant software via a high-speed network interface for analysis and evaluation.

A user uses a visual interface to perform data analysis and evaluation.

The relationship between a V2X on-board unit (OBU) and the V2X PC5 is that the V2X OBU, mounted on the vehicle, uses the V2X PC5 protocol to communicate with other vehicles. The V2X OBU is connected to a PC5 communication module of the vehicle through a PC5 interface and exchanges data using the PC5 protocol. The PC5 communication module is configured to implement functions and communication capabilities of the PC5 protocol, including receiving and sending PC5 messages and handling PC5 communication interruptions.

The V2X OBU broadcasts BSMs at a frequency of 10 Hz, which include essential vehicle information, vehicle dynamic information, and critical event information. Detailed content of the BSMs is as shown in Table 1. Data sending requirements specify sending conditions for four types of data units:
mandatory: indicating that the system should send the data;
conditionally mandatory: indicating that the system should send the data when a trigger condition is met;
optional: indicating that the system automatically chooses whether or not to send the data; and
not required: indicating that the system should not send the data.

TABLE 1
BSM data elements

| | | Data Unit | |
|---|---|---|---|
| Data Unit/Field | Data Unit Definition | Type | Test Method |
| DE_MsgCount | Message serial number | Mandatory | Shielded |
| | | | chamber static |
| | | | test |
| id | Temporary vehicle ID | Mandatory | Shielded |
| | | | chamber static |
| | | | test |
| DE_DSecond | Millisecond time point | Mandatory | Shielded |
| | within 1 minute | | chamber static |
| | | | test |
| DE_TimeConfidence | Time confidence | Optional | Shielded |
| | | | chamber static |
| | | | test |
| >DE_Latitude | Latitude value | Mandatory | Shielded |
| | | | chamber |
| | | | dynamic test |
| >DE_Longitude | Longitude value | Mandatory | Shielded |
| | | | chamber |
| | | | dynamic test |
| >DE_Elevation | Vehicle elevation | Not required | Shielded |
| | | | chamber |
| | | | dynamic test |
| >DE_SemiMajorAxisAccuracy | Positioning system | Mandatory | Shielded |
| | accuracy, indicating a | | chamber |
| | major semi-axis of an | | dynamic test |
| | error ellipse | | |
| >DE_SemiMinorAxisAccuracy | Positioning system | Mandatory | Shielded |
| | accuracy, indicating a | | chamber |
| | minor semi-axis of an | | dynamic test |
| | error ellipse | | |
| >DE_SemiMajorAxisOrientation | Positioning system | Mandatory | Shielded |
| | accuracy, indicating an | | chamber |
| | angle between a major | | dynamic test |
| | axis of an error ellipse | | |
| | and the true north | | |
| | direction | | |
| >DE_PositionConfidence | Comprehensive vehicle | Mandatory | Shielded |
| | position accuracy and the | | chamber static |
| | type of a positioning | | test |
| | plug-in | | |
| >DE_ElevationConfidence | The value indicates | Optional | Shielded |
| | accuracy of a vehicle | | chamber static |
| | elevation at a 95% | | test |
| | confidence level | | |
| DE_TransmissionState | Vehicle gear information | Mandatory | Shielded |
| | | | chamber |
| | | | dynamic test |
| DE_Speed | Vehicle speed | Mandatory | Road test |
| DE_Heading | Vehicle heading angle | Mandatory | Road test |
| DE_SteeringWheelAngle | Vehicle steering wheel | Mandatory | Shielded |
| | angle | | chamber |
| | | | dynamic test |
| >DE_SpeedConfidence | The value indicates | Optional | Shielded |
| | accuracy of a vehicle | | chamber static |
| | speed at a 95% | | test |
| | confidence level | | |
| >DE_HeadingConfidence | The value indicates | Optional | Shielded |
| | accuracy of a vehicle | | chamber static |
| | heading angle at a 95% | | test |
| | confidence level | | |
| >DE_SteeringWheelAngleConfidence | The value indicates | Optional | Shielded |
| | accuracy of a vehicle | | chamber static |
| | steering wheel angle at a | | test |
| | 95% confidence level | | |
| >DE_Acceleration(Longitudinal) | Vehicle longitudinal | Mandatory | Road test |
| | acceleration | | |
| >DE_Acceleration(Lateral) | Vehicle lateral | Mandatory | Road test |
| | acceleration | | |
| >DE_VerticalAcceleration | Magnitude of | Mandatory | Road test |
| | acceleration in the | | |
| | vertical direction | | |
| >DE_YawRate | Vehicle yaw rate | Mandatory | Road test |
| >DE_BrakePedalStatus | Indicating whether a | Mandatory | Shielded |
| | brake pedal is depressed | | chamber |
| | | | dynamic test |
| >DE_BrakeAppliedStatus | Braking statuses of four | Mandatory | Shielded |
| | wheels | | chamber |
| | | | dynamic test |
| >DE_TractionControlStatus | Defining a real-time | Mandatory | Shielded |
| | status of a traction control | | chamber event |
| | system (TCS) | | trigger test |
| >DE_AntiLockBrakeStatus | Defining a status of an | Optional | Shielded |
| | anti-lock braking system | | chamber event |
| | (ABS) | | trigger test |
| >DE_StabilityControlStatus | Status of a dynamic | Optional | Shielded |
| | vehicle stability control | | chamber event |
| | system | | trigger test |
| >DE_BrakeBoostApplied | Status of a brake boost | Optional | Shielded |
| | system, indicating a | | chamber event |
| | vehicle emergency | | trigger test |
| | braking status | | |
| >DE_AuxiliaryBrakeStatus | Indicating a status of an | Optional | Shielded |
| | auxiliary brake system | | chamber event |
| | (usually handbrake) | | trigger test |
| >DE_VehicleWidth | Vehicle width | Mandatory | Shielded |
| | | | chamber static |
| | | | test |
| >DE_VehicleLength | Vehicle length | Mandatory | Shielded |
| | | | chamber static |
| | | | test |
| >DE_VehicleHeight | Vehicle height | Optional | Shielded |
| | | | chamber static |
| | | | test |
| >DE_BasicVehicleClass | Basic vehicle class | Mandatory | Shielded |
| | | | chamber static |
| | | | test |
| >DE FuelType | Fuel type | Optional | Shielded |
| | | | chamber static |
| | | | test |
| >DE_VehicleEventFlags | A range of special vehicle | Conditionally | Shielded |
| | statuses | mandatory | chamber event |
| | | | trigger test |
| >DF_PathHistory | Vehicle path history (PH) | Conditionally | Shielded |
| | | mandatory | chamber |
| | | | dynamic test |
| >>DF_FullPositionVector | Complete reference point | Not required | Shielded |
| | information of a PH | | chamber |
| | | | dynamic test |
| >>DE_GNSSstatus | Including a device | Optional | Shielded |
| | working status, a satellite | | chamber |
| | lock status, and | | dynamic test |
| | correction information. | | |
| | GNSS system includes | | |
| | the global positioning | | |
| | system (GPS), Beidou | | |
| | (BD), and other related | | |
| | systems and device | | |
| >>DF_PathHistoryPointList | A list of PH points, | Mandatory | Shielded |
| | defining the vehicle path | | chamber |
| | history | | dynamic test |
| >>>DF_PathHistoryPoint | Path history points of a | Mandatory | Shielded |
| | vehicle | | chamber |
| | | | dynamic test |
| >>>>DF_PositionOffsetLLV | Three-dimensional | Mandatory | Shielded |
| | relative position (relative | | chamber |
| | longitude, relative | | dynamic test |
| | latitude, and relative | | |
| | altitude) of a vehicle. A | | |
| | deviation is equal to the | | |
| | true value minus the | | |
| | reference value. | | |
| >>>>>DF_PositionOffsetLL | Latitude and longitude | Mandatory | Shielded |
| | deviation, describing a | | chamber |
| | relative position of a | | dynamic test |
| | coordinate point | | |
| >>>>>DF_VerticalOffset | Latitude and longitude | Optional | Shielded |
| | deviation, describing a | | chamber |
| | relative position of a | | dynamic test |
| | coordinate point | | |
| >>>>DE_TimeOffset | Defining a deviation of a | Mandatory | Shielded |
| | current description time | | chamber |
| | point (earlier) from a | | dynamic test |
| | reference time point | | |
| | (later) | | |
| >>>>DE_Speed | Vehicle speed | Optional | Shielded |
| | | | chamber |
| | | | dynamic test |
| >>>>DF_PositionConfidenceSet | Comprehensive vehicle | Not required | Shielded |
| | position accuracy | | chamber static |
| | | | test |
| >>>>DE_CoarseHeading | Coarse-grained heading | Optional | Shielded |
| | angle of a vehicle | | chamber static |
| | | | test |
| >DF_PathPrediction | Predicted path of a | Mandatory | Shielded |
| | vehicle | | chamber |
| | | | dynamic test |
| >>DE_RadiusOfCurvature | Radius of curvature of a | Mandatory | Shielded |
| | predicted path ahead of a | | chamber |
| | vehicle | | dynamic test |
| >>DE_Confidence | Indicating a confidence | Mandatory | Shielded |
| | degree of a predicted path | | chamber |
| | of a vehicle | | dynamic test |
| >DE_ExteriorLights | Status of exterior lights of | Conditionally | Shielded |
| | a vehicle | mandatory | chamber event |
| | | | trigger test |
| >DE_ResponseType | Current driving status or | Conditionally | Shielded |
| | driving behavior of an | mandatory | chamber event |
| | emergency vehicle | | trigger test |
| >DE_SirenInUse | Status of a siren or any | Conditionally | Shielded |
| | dedicated sounding | mandatory | chamber event |
| | device on an emergency | | trigger test |
| | vehicle | | |
| >DE_LightBarInUse | Working status of | Conditionally | Shielded |
| | warning lights or an | mandatory | chamber event |
| | external dedicated display | | trigger test |
| | device on an emergency | | |
| | vehicle | | |

Based on the above V2X-PC5 communication protocol and preset BSM content, data communication and vehicle data consistency testing are performed.

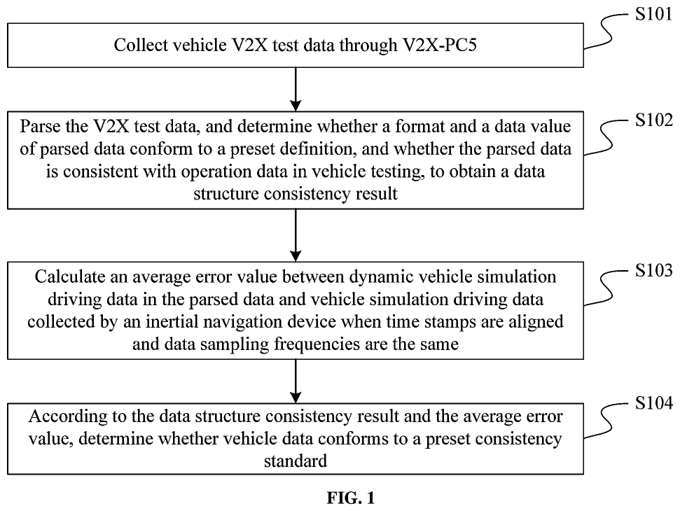

As shown in FIG. 1, a data processing process of vehicle data consistency testing in V2X is as follows:

S101: Collect vehicle V2X test data based on a V2X-PC5 communication protocol.

According to the present application, vehicle data consistency in V2X is tested in two types of environments, one is an anechoic chamber and the other is an open environment that features a smooth road surface and meets the open sky environment requirements.

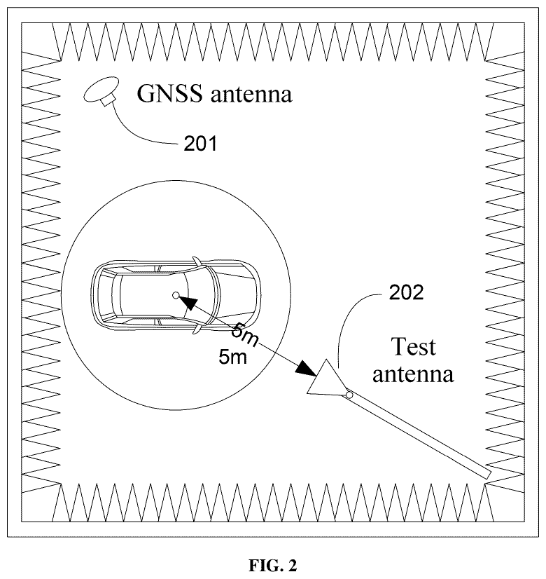

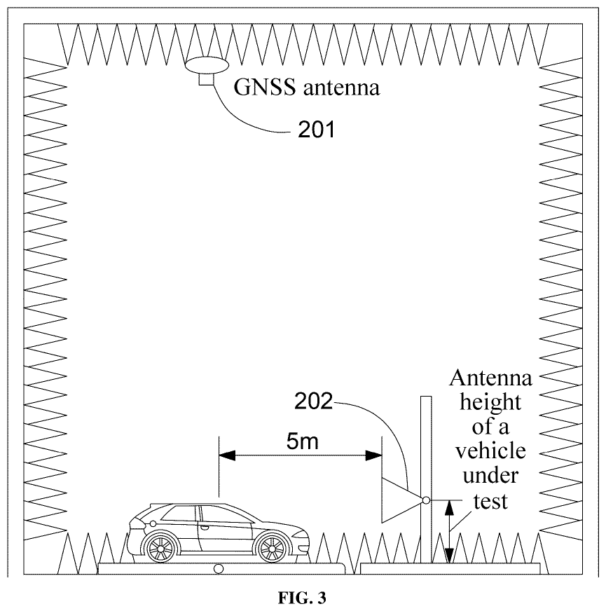

As shown in FIG. 2 and FIG. 3, the laboratory test environment includes an anechoic chamber with a hub rotation function. The chamber is equipped with a GNSS simulator 201 and a V2X PC5 message receiving instrument 301.

In the experiment, the V2X PC5 message receiving instrument 301 and the GNSS simulator 201 are respectively connected to a test antenna port 202 and a GNSS antenna port in the chamber. A horizontal distance between the test antenna port 202 and the center of a vehicle under test is five meters, and the height of the test antenna port 202 is the same as the center height of an LTE-V2X antenna of the vehicle under test. The vehicle under test is mounted on a turntable and a hub, the turntable allows the vehicle under test to horizontally rotate 0° to 360°, while the hub enables the vehicle under test to operate in place within the shielded chamber.

As shown in FIG. 4, the open test environment does not include any other V2X-enabled vehicles or systems, apart from the V2X PC5 message receiving instrument 301 connected to a vehicle-data dynamic collection unit 302. To ensure accurate data collection from the vehicle under test, the test environment should allow the vehicle to reach the speed of up to 80 km/h and provide sufficient space for acceleration and deceleration.

On the test road, the vehicle-data dynamic collection unit collects real data from the vehicle under test. It is necessary to ensure that the accuracy of the collected data exceeds accuracy requirements specified for the vehicle under test.

The V2X PC5 message receiving instrument 301 is mounted inside the vehicle under test and connected to a test antenna mounted on the vehicle body for ensuring stable reception of BSMs sent by the vehicle.

Based on the preset test environment, the vehicle is tested as follows:

### Shielded Chamber Static Testing:

Shielded chamber static testing is a method to evaluate the vehicle data consistency. A testing process is as follows:

a) Drive the vehicle under test into the shielded chamber and onto the turntable. Ensure the vehicle is accurately positioned and securely fixed on the turntable. Turn off the engine for preparation.

b) Start the V2X PC5 message receiving instrument 301 to receive and forward BSMs from an infrastructure module to a test system, and record content of each BSM received, from first to last.

c) Start the vehicle under test and simultaneously start the GNSS simulator 201 to send preset fixed position data, ensuring the vehicle to transmit BSMs normally.

d) Restart the vehicle under test to resume BSM transmission. The V2X PC5 message receiving instrument 301 continuously records all received BSMs, and the test duration is not less than 600 seconds.

e) Repeat the above step d) multiple times (for example, three times).

f) During the test, directly read and record the V2X messages received by the test system to verify whether the test items listed in Table 1 meet the technical requirements for the broadcast data elements of the vehicle under test.

### Shielded Chamber Dynamic Test:

Shielded chamber dynamic testing is another method to evaluate the vehicle data consistency, including the following steps:

a) Drive the vehicle under test into the shielded chamber and onto the turntable. Ensure the vehicle is accurately positioned and securely fixed on the turntable. Turn off the engine for preparation.

b) Start the V2X PC5 message receiving instrument 301 to receive and forward BSMs from an infrastructure module to a test system, and record content of each BSM received, from first to last.

c) Start the vehicle under test and simultaneously start the GNSS simulator 201 to send preset trajectory data, ensuring the vehicle under test to transmit BSMs normally.

d) The driver of the vehicle under test is guided by voice to follow the preset trajectory, ensuring error between the hub rolling linear speed and the speed in the GNSS trajectory to be within ±1 km/h, and the speed and trajectory parameter values in the BSMs meet test requirements. In addition, adjust the vehicle heading angle using the turntable to align with the direction data in the GNSS trajectory.

e) The driver performs corresponding driving actions, such as shifting gears, braking, and steering, as guided by voice. Record the sequence, time, and frequency of the action commands to match parameter value testing of the gear position, braking system, and steering wheel angle in the BSMs.

f) The effective duration of the test is at least 600 seconds and includes various trajectories at different speeds, such as fixed geographical positions, straight lines (at low, medium, and high speeds), and different directions.

g) During the test, directly read and record the V2X messages received by the test system to verify whether the test items listed in Table 1 meet the technical requirements for the broadcast data elements of the vehicle under test.

### Shielded Chamber Event Trigger Testing:

In order to ensure data consistency, the following method is used in shielded chamber event trigger testing:

a) Drive the vehicle under test into the shielded chamber and onto the turntable. By aligning the position of the vehicle under test, ensure that both the front and rear wheels are aligned with the front and rear hub groups of the turntable. Secure the vehicle on the turntable and turn off the engine for preparation.

b) Start the V2X PC5 message receiving instrument 301 to forward received BSMs to a test system, and record content of each BSM received, from first to last.

c) Start the vehicle under test and simultaneously start the GNSS simulator 201 to send preset GNSS trajectory data, ensuring the vehicle to transmit BSMs normally.

d) Guide the driver of the vehicle under test by voice, and control the running of the vehicle under test, to ensure the error between the rolling linear speed of the turntable and the speed in the GNSS trajectory to be within 1 km/h. In addition, control the turntable to rotate the heading angle of the vehicle under test, to ensure the heading angle of the vehicle under test to be consistent with the direction data in the GNSS trajectory.

e) Guide by voice the driver of the vehicle under test to trigger corresponding events, for example, brake system status trigger (ABS, TCS, or ESP), emergency vehicle event (emergency status, siren status, warning light status), key vehicle event (danger warning signal, emergency braking, tire undervoltage, airbag pop-up, and simulation trigger), and lights around the vehicle body (turn signals, dipped headlight, parking lights). In addition, record the sequence, time, frequency, and duration of action commands to complete parameter value testing of the brake system status, emergency vehicles, key events, and auxiliary lights in the BSMs.

f) Ensure that the effective testing duration is not less than 600 seconds.

g) During the above test, directly read and record the V2X messages received by the test system to verify whether the test items listed in Table 1 meet the technical requirements for the broadcast data elements of the vehicle under test.

### Road Test Method:

To ensure the accuracy and reliability of road tests, the following steps are performed:

a) First, select a qualified test site free from strong electromagnetic interference sources, such as power stations. This avoids external factors affecting the test results.

b) Next, start the vehicle under test and adjust to a state for normally broadcasting BSMs, such as turning off the privacy mode. Drive the vehicle for a certain distance at any speed to ensure BSMs are sent at the specified frequency.

c) Start the V2X-PC5 data collection, recording, and parsing system and place the receiving antenna on the vehicle roof to receive GNSS signals. Check the display light status corresponding to the V2X-PC5 data collection, recording, and parsing system, to confirm normal operation, then start receiving and storing BSMs from the vehicle under test.

d) Once the vehicle under test is successfully connected to the V2X-PC5 data recording and parsing system, install a high-precision inertial navigation device on the vehicle to record the speed, acceleration, heading angle, and other status information of the vehicle.

e) The vehicle under test should follow an elliptical trajectory, with a recommended speed not exceeding 60 km/h to ensure safety. The test lasts approximately 10 minutes and includes various driving statuses such as constant speed, acceleration, deceleration, left turns (using the left turn signal), and right turns (using the right turn signal). During the test process, record the time point for each status, and ensure the V2X-PC5 data parsing system collects, stores, and parses real-time information broadcast by the vehicle under test.

f) After the test, park the vehicle in a safe location. Verify that the V2X-PC5 data recording and parsing system has recorded the data in the driving process, and check the data against the recorded time points of different statuses during testing, to ensure that the data recorded during testing is complete and without obvious errors. Also, check whether data stored by the high-precision inertial navigation device is complete and free of anomalies such as time jumps. Once confirmed, store all data and end the test.

g) Finally, process the V2X test data according to requirements to draw a conclusion.

The principle of data processing is to verify whether the V2X vehicle normally sends BSMs, by comparing and analyzing the real status information of the vehicle under test and the broadcast information, and ensure data accuracy meets the standard requirements, so as to ensure quality of data sent by the V2X vehicle supports early warning applications.

During data processing, first, the high-precision inertial navigation device needs to be mounted on the vehicle to record and store the real status information of the vehicle. Next, the data is processed to determine whether the data consistency meets the standard.

S102: Parse the V2X test data, and determine whether a format and a data value of parsed data conform to a preset definition, and whether the parsed data is consistent with operation data in vehicle testing, to obtain a data structure consistency result.

The data format requirements may be parsed by a tester using the V2X-PC5 data collection, recording, and parsing system. Once the data packet is parsed according to the requirements and the data values fall within a reasonable range, it is considered that the data format of the vehicle under test meets the test requirements. Specific steps are as follows:

The tester uses the V2X-PC5 data collection, recording, and parsing system to parse the collected data packets. The system automatically parses the data packets and extracts data according to defined format specifications.

Check whether the parsed data conforms to the data format requirements, including data fields, data types, and data lengths. If all data fields are parsed correctly and the data values fall within the reasonable range, determine that the data format of the vehicle under test meets the test requirements.

For information such as turn signals and abnormal vehicle signals, the tester can trigger the scenario information on site and uses the analysis software to determine whether the data is consistent. Specific steps are as follows:

The tester triggers the corresponding scenario information on the vehicle under test, such as activating the left turn signal or the abnormal vehicle signal.

Use the parsing software to view the parsed data in real time and compare the data with the actually triggered scenario information.

Verify that the parsed data is consistent with the actual operation, including data content, data format, and data values. If the data displayed by the parsing software matches the actually triggered scenario information, the data is considered correctly parsed.

S103: Calculate an average error value between dynamic vehicle driving data in the parsed data and vehicle driving data collected by the high-precision inertial navigation device when time stamps are aligned and data sampling frequencies are the same.

For dynamic information such as acceleration, speed, and position, an EXCEL format of the data received by the V2X-PC5 data collection, recording, and parsing system may be compared with data collected by the high-precision inertial navigation device. Specific steps are as follows:

The data collected by the V2X-PC5 data collection, recording, and parsing system is exported as an EXCEL file.

Similarly, the high-precision inertial navigation device collects data and exports the data as an EXCEL file.

Ensure time stamp alignment between the two sets of data for comparative analysis at the same time points.

Compare the values of dynamic information such as position, speed, and acceleration, and calculate the errors.

According to the test requirements, determine whether the average error value for the test validity period meets the standard requirements.

S104: According to the data structure consistency result and the average error value, determine whether vehicle data conforms to a preset consistency standard.

If both the data structure consistency result and the average error value are within the preset error range, the preset consistency standard is considered met, and vice versa.

It should be noted that if the error in the analysis result is too large, specific causes need to be analyzed, such as frame loss, missing transmission, delay, or other reasons, and a detailed analysis should be conducted based on the actual situation. Specific steps are as follows:

Analyze the causes of large analysis error, which may be due to issues with the V2X-PC5 system, such as frame loss, missing transmissions, or delays.

Check for frame loss during data collection by using the packet serial number.

Check delays in data transmission, which may increase due to network transmission or system processing.

Analyze whether the data collection system has performance issues, such as hardware failures or inaccurate parsing algorithms.

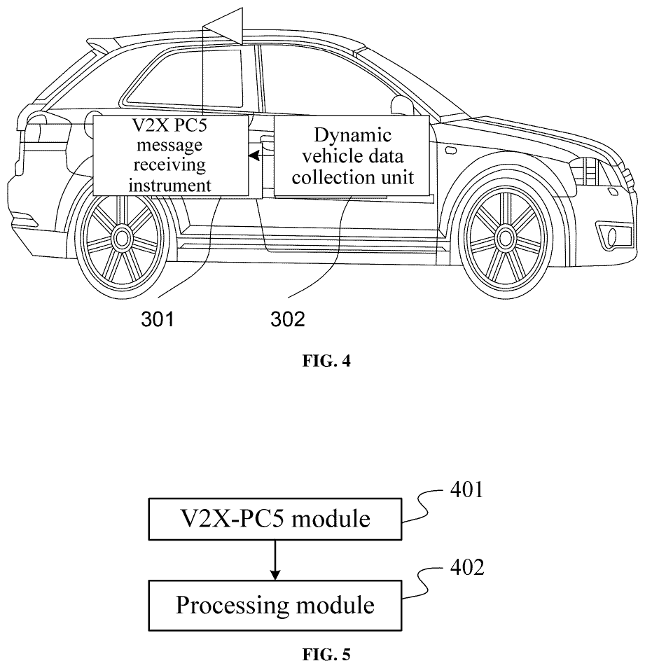

As shown in FIG. 5, the present application further provides a device for testing vehicle data consistency in V2X, including: a V2X-PC5 module 401 and a processing module 402.

The V2X-PC5 module 401 receives BSMs sent by a vehicle under test.

The processing module 402 is configured to: collect vehicle V2X test data; parse the V2X test data, and determine whether a format and a data value of parsed data conform to a preset definition, and whether parsed data is consistent with operation data in vehicle testing, to obtain a data structure consistency result; calculate an average error value between dynamic data in the parsed data and driving data collected by an inertial navigation device when time stamps are aligned and data sampling frequencies are the same; and according to the data structure consistency result and the average error value, determine whether vehicle data conforms to a preset consistency standard.

The present application is described with reference to the flowcharts and/or block diagrams of the method, the apparatus (device), and the computer program product according to the embodiments of the present disclosure. It should be understood that computer program instructions may be used to implement each process and/or each block in the flowcharts and/or the block diagrams and a combination of a process and/or a block in the flowcharts and/or the block diagrams. These computer program instructions may be provided for a general-purpose computer, a dedicated computer, an embedded processor, or a processor of another programmable data processing device to generate a machine, so that the instructions executed by a computer or a processor of another programmable data processing device generate an apparatus for implementing a specific function in one or more processes in the flowcharts and/or in one or more blocks in the block diagrams.

These computer program instructions may be stored in a computer-readable memory that can instruct the computer or other programmable data processing devices to work in a specific manner such that the instructions stored in the computer-readable memory generate an artifact that includes an instruction apparatus. The instruction apparatus implements a specific function in one or more processes in the flowcharts and/or in one or more blocks in the block diagrams.

It should be noted that the terms used in the present application are for the purpose of describing specific examples only and are not intended to limit the present application. In the description and claims of the present disclosure, unless otherwise explicitly indicated, the words “a”, “one”, “a type” and/or “the” are not specifically singular, and may also include the plural forms. In addition, terms “include”, “comprise”, or any other variations thereof are intended to cover non-exclusive including, so that a process, a method, or a device including a series of elements not only includes those elements, but also includes other elements that are not explicitly listed, or also includes inherent elements of the process, the method, or the device. In case there are no more restrictions, an element limited by the statement “including a . . . ” does not exclude the presence of additional identical elements in the process, the method, the article, or the device that includes the element.

It should be noted that orientations or position relationships indicated by terms “center”, “upper”, “lower”, “left”, “right”, “vertical”, “horizontal”, “inner”, “outer”, etc. are orientation or position relationships shown in the accompanying drawings, and these terms are only intended to facilitate description of the present application and simplify the description, rather than indicating or implying that the referred apparatus or element must have a specific orientation and be constructed and operated in a specific orientation, and therefore should not be construed as limiting the present application. Unless otherwise clearly specified and limited, terms such as “mounted”, “connected with” and “connected to” should be understood in a broad sense. For example, the term may be a fixed connection, a detachable connection or an integral connection; may be a mechanical connection or an electrical connection; and may be a direct connection, an indirect connection by means of an intermediate medium, or internal communication between two elements. Those of ordinary skill in the art may understand the specific meanings of the above terms in the present application based on specific situations.

The above-mentioned embodiments and/or implementations are only used to illustrate the preferred embodiments and/or implementations for realizing the technology of the present disclosure, and do not restrict the implementation of the technology of the present disclosure in any form. Those skilled in the art can make changes or modifications to other equivalent embodiments without departing from the scope of the technical means disclosed in the present disclosure, but they should still be regarded as substantially the same technology or embodiments as the present disclosure.

Specific embodiments are used for illustrating principles and implementations of the present disclosure herein. The description of the embodiments above is only used for helping understand the method and its core concept of the present disclosure. The above description is only the preferred implementation of the present application. It should be pointed out that since the text expression is limited while there are objectively infinite specific structures, those of ordinary skill in the art can also perform several improvements, embellishments or changes without departing from the principle of the present application, or can combine the foregoing technical features in appropriate ways. These improvements, embellishments, changes or combinations, or those that directly apply the concepts and technical solutions of the present disclosure to other occasions without improvement, shall be regarded as falling within the protection scope of the present application.

What is claimed is:

1. A method for testing vehicle data consistency in vehicle to everything (V2X), comprising:
collecting vehicle V2X test data transmitted based on a V2X-PC5 communication protocol;
parsing the V2X test data, and determining whether a format and a data value of parsed data conform to a preset definition, and whether the parsed data is consistent with operation data in vehicle testing, to obtain a data structure consistency result;
calculating an average error value between dynamic vehicle driving data in the parsed data and vehicle driving data collected by an inertial navigation device when time stamps are aligned and data sampling frequencies are the same; and
according to the data structure consistency result and the average error value, determining whether vehicle data conforms to a preset consistency standard.

2. The method for testing vehicle data consistency in V2X according to claim 1, wherein said determining whether a format and a data value of parsed data conform to a preset definition comprises:
determining whether the parsed data conforms to a format of a basic safety message (BSM).

3. The method for testing vehicle data consistency in V2X according to claim 1, wherein in said determining whether a format and a data value of parsed data conform to a preset definition, said determining whether a data value conforms to a preset definition comprises:
determining whether the data value falls between a data value range defined during testing.

4. The method for testing vehicle data consistency in V2X according to claim 1, wherein the V2X test data comprises shielded chamber static test data, shielded chamber dynamic test data, and shielded chamber event trigger test data.

5. The method for testing vehicle data consistency in V2X according to claim 4, wherein steps for obtaining the shielded chamber static test data comprise:
driving a vehicle under test into a shielded chamber, fixing the vehicle on a turntable, and powering off the vehicle;
starting a V2X PC5 message receiving instrument, to start recording basic safety messages (BSMs) from the vehicle;
starting the vehicle under test and simultaneously starting a global navigation satellite system (GNSS) simulator to send vehicle static information;
restarting the vehicle under test to restart sending BSMs, and recoding, by the V2X PC5 message receiving instrument, all BSMs received; and
repeating the previous step to obtain a plurality of pieces of vehicle test data corresponding to the vehicle static information.

6. The method for testing vehicle data consistency in V2X according to claim 4, wherein steps for obtaining the shielded chamber dynamic test data comprise:
driving a vehicle under test into a shielded chamber, fixing the vehicle on a turntable, and powering off the vehicle;
starting a V2X PC5 message receiving instrument, to start recording basic safety messages (BSMs) from the vehicle;
starting the vehicle under test and simultaneously starting a global navigation satellite system (GNSS) simulator to send vehicle dynamic data;
controlling an error between a rolling linear speed of the turntable and a speed in a GNSS trajectory to be within ±1 km/h, and a heading angle of the vehicle under test to be consistent with direction data in the GNSS trajectory;
guiding by voice, a driver of the vehicle under test to perform a driving action, and starting sending BSMs; and
recording, by the V2X PC5 message receiving instrument, all BSMs received, to obtain vehicle test data corresponding to the vehicle dynamic information.

7. The method for testing vehicle data consistency in V2X according to claim 4, wherein steps for obtaining the shielded chamber event trigger test data comprise:
driving a vehicle under test into a shielded chamber, fixing the vehicle on a turntable, and powering off the vehicle;
starting a V2X PC5 message receiving instrument, to start recording basic safety messages (BSMs) from the vehicle;
starting the vehicle under test and simultaneously starting a global navigation satellite system (GNSS) simulator to send vehicle dynamic data;
controlling an error between a rolling linear speed of the turntable and a speed in a GNSS trajectory to be within ±1 km/h, and a heading angle of the vehicle under test to be consistent with direction data in the GNSS trajectory;
guiding by voice, a driver of the vehicle under test to trigger a defined event, and starting sending BSMs; and
recording, by the V2X PC5 message receiving instrument, all BSMs received, to obtain vehicle test data corresponding to the vehicle dynamic information.

8. The method for testing vehicle data consistency in V2X according to claim 5, wherein experimental conditions for obtaining the test data comprise:
a laboratory test environment is an anechoic chamber; and
a road test environment meets open sky environment requirements.

9. The method for testing vehicle data consistency in V2X according to claim 2, wherein the BSM comprises the following types:
mandatory: indicating that a system sends a data unit in each cycle;
conditionally mandatory: indicating that a system sends a data unit when a specific triggering condition is met;
optional: indicating that a system autonomously determines whether or not to send a data unit; and
not required: indicating that a system does not send a data unit.

10. A device for testing vehicle data consistency in vehicle to everything (V2X), comprising:
a V2X-PC5 module and a processing module, wherein
the V2X-PC5 module receives basic safety messages (BSMs) sent by a vehicle under test; and
the processing module is configured to: collect vehicle V2X test data; parse the V2X test data, and determine whether a format and a data value of parsed data conform to a preset definition, and whether the parsed data is consistent with operation data in vehicle testing, to obtain a data structure consistency result; calculate an average error value between dynamic vehicle driving data in the parsed data and vehicle driving data collected by an inertial navigation device when time stamps are aligned and data sampling frequencies are the same; and according to the data structure consistency result and the average error value, determine whether vehicle data conforms to a preset consistency standard.

11. The method for testing vehicle data consistency in V2X according to claim 6, wherein experimental conditions for obtaining the test data comprise:
a laboratory test environment is an anechoic chamber; and
a road test environment meets open sky environment requirements.

12. The method for testing vehicle data consistency in V2X according to claim 7, wherein experimental conditions for obtaining the test data comprise:
a laboratory test environment is an anechoic chamber; and
a road test environment meets open sky environment requirements.
